(19) United States
(12) Patent Application Publication
(10) Pub. No.: US 2018/0130639 A1
(43) Pub. Date: May 10, 2018

(54) EXTERNAL PLASMA SYSTEM

(71) Applicants: Michael Nicholas Vranich, (US); Paul Frederick Smith, (US)

(72) Inventors: Michael Nicholas Vranich, San Jose, CA (US); Paul Frederick Smith, San Jose, CA (US)

(21) Appl. No.: 15/571,478

(22) PCT Filed: Apr. 29, 2016
(86) PCT No.: PCT/US2016/030235

§ 371 Date: Nov. 2, 2017

Related U.S. Application Data
(60) Provisional application No. 62/156,694, filed on May 4, 2015.

(51) Int. Cl. H01J 37/32; H05H 1/46

(52) U.S. Cl. CPC H01J 37/32357; H01J 37/32522; H05H 2001/4667; H01J 37/32082; H05H 1/46

(57) ABSTRACT

Methods and systems for generating a plasma using an external plasma system are described. The plasma system may include an energy coupling device (e.g., an electromagnetic coil or capacitor) that is submersed within a liquid coolant and powered by an RF source. In some embodiments, a C-shaped magnetic core may be submersed within the liquid coolant and one or more plasma tubes may be arranged within an opening of the C-shaped magnetic core between the ends of the C-shaped magnetic core. To generate a plasma in a first tube of the one or more plasma tubes, a gas may be inserted into the first tube while the RF source drives a coil surrounding a portion of the C-shaped magnetic core to couple electromagnetic energy into the gas within the first tube.

### BACKGROUND

Plasmas may be used for generating reactions with solids, liquids, and gases for various industrial applications, such as thin-film deposition, photoresist stripping, and etching. In some cases, an industrial application may require direct exposure of a material being processed to a plasma. The plasma may be generated using various types of energy including direct current (DC), radio frequency (RF), and microwave. DC discharges may be achieved by applying a voltage between two electrodes in a gas. RF discharges may be achieved by capacitively or inductively coupling energy from a power supply into the plasma. Microwave discharges may be produced by coupling a microwave energy source to a discharge chamber containing a gas. In some cases, plasma discharges may be generated in a manner such that both the charged species constituting the plasma and the neutral species, which may be activated by the plasma, are in contact with the material being processed. In other cases, the plasma discharges may be generated remotely from the material being processed, such that relatively few of the charged species come into contact with the material being processed while the neutral species is in contact with the material being processed. Such a plasma discharge may be referred to as a remote or downstream plasma discharge.

### BRIEF DESCRIPTION OF THE DRAWINGS

FIG. 1 depicts one embodiment of an external plasma system.

FIGS. 2A-2B depicts various embodiments of a C-shaped magnetic core.

FIGS. 2C-2D depict various embodiments of a top plan view of a C-shaped magnetic core.

FIG. 2E depicts one embodiment of an opening between the ends of a C-shaped magnetic core.

FIG. 2F depicts another embodiment of an opening between the ends of a C-shaped magnetic core.

FIG. 2G is one example of a cross-sectional view taken along line Y-Y of FIG. 2F.

FIG. 2H depicts one embodiment of an opening between the ends of a C-shaped magnetic core in which a first process tube and a second process tube have been positioned.

FIG. 2I depicts one embodiment of an opening between the ends of a C-shaped magnetic core in which a first process tube and a second process tube have been positioned.

FIG. 2J depicts one embodiment of an opening between the ends of a C-shaped magnetic core in which two process tubes have been positioned.

FIGS. 3A-3D depict one embodiment of a portion of an external plasma system including a chamber for submersing a reaction tube and one or more energy coupling circuits in a liquid coolant while generating a plasma within the reaction tube.

FIGS. 3E-3G depict one embodiment of a process tube assembly.

FIG. 4A depicts one embodiment of an external plasma system.

FIG. 4B depicts an alternative embodiment of an external plasma system.

FIG. 4C depicts one embodiment of a capacitor.

FIG. 4D depicts one embodiment of an external plasma system.

FIG. 5A is a flowchart describing one embodiment of a process for generating a plasma using an external plasma system.

FIG. 5B is a flowchart describing another embodiment of a process for generating a plasma using an external plasma system.

FIG. 5C is a flowchart describing an alternative embodiment of a process for generating one or more plasmas using an external plasma system.

FIG. 6A depicts another embodiment of an external plasma system.

FIG. 6B depicts an alternative embodiment of an external plasma system.

FIG. 6C depicts one embodiment of a C-shaped magnetic core with an opening between the ends of the C-shaped magnetic core in which a first process tube and a second process tube have been positioned.

FIG. 6D depicts one embodiment of an opening between the ends of a C-shaped magnetic core in which a first process tube and a second process tube have been positioned.

FIG. 6E depicts another embodiment of an external plasma system.

FIG. 7A is a flowchart describing one embodiment of a process for generating a plasma using an external plasma system.

FIG. 7B is a flowchart describing another embodiment of a process for generating a plasma using an external plasma system.

### DETAILED DESCRIPTION

Technology is described for generating a plasma using an external (upstream or downstream) plasma system. The plasma system may include a magnetic core, a capacitor, or a combination of magnetic cores and capacitors that are completely or partly submersed within a liquid coolant and powered by one or more RF sources (e.g., a 50 Hz to 200 MHz RF power source). The magnetic core may comprise a toroidal-shaped, C-shaped, U-shaped, or E-shaped magnetic core that is wrapped with an inductive coil having multiple turns or loops and that is wholly or partially submersed in the liquid coolant, such as a perfluorinated compound (PFC) liquid coolant for heat transfer. The liquid coolant may comprise a heat transfer liquid, a dielectric liquid coolant, or a non-dielectric liquid coolant. The liquid coolant may include, for example, glycol, ethylene glycol, propylene glycol, a PFC coolant, or liquid polytetrafluoroethylene (PTFE). In one example, the liquid coolant may be operated within a range between −50 degrees Celsius and +50 degrees Celsius.

In some embodiments, a C-shaped magnetic core may be wholly or partially submersed in a liquid coolant with one or more plasma tubes that are arranged within an opening of the C-shaped magnetic core between the ends of the C-shaped magnetic core. To generate a plasma in a first reaction tube of the one or more plasma tubes, a gas may be injected or inserted into the first reaction tube while an RF source drives a primary winding of the C-shaped magnetic core to couple electromagnetic energy into the gas within the first reaction tube. In this case, the plasma may be generated within the first reaction tube by coupling electromagnetic energy into the gas while the C-shaped magnetic core is submersed in the liquid coolant. The first reaction tube may comprise a quartz or ceramic tube. The gas may comprise various gases such as hydrogen, helium, nitrogen, oxygen, clean dry air (CDA), neon, argon, fluorine, krypton, xenon, NF3, or methane (CH4) and other gaseous hydrocarbon derivatives (CₓH_{y}).

In some embodiments, a capacitor comprising two capacitor plates may be wholly or partially submersed in a liquid coolant with one or more plasma tubes arranged between the two capacitor plates. In one example, the two capacitor plates may comprise machined parts that are clamped to a first reaction tube of the one or more plasma tubes. The first reaction tube may comprise a quartz or ceramic tube. In another example, the two capacitor plates may correspond with two capacitor electrodes that have been deposited or plated onto the outer surface of the first reaction tube. The capacitor plates or electrodes may comprise a metal, metal alloy, or a combination of metals, such as aluminum, copper, silver, nickel, or gold. To generate a plasma in a first reaction tube of the one or more plasma tubes, a gas may be injected or inserted into the first reaction tube while an RF source drives the capacitor plates to couple electromagnetic energy into the gas within the first reaction tube. In this case, the plasma may be generated within the first reaction tube by coupling electromagnetic energy into the gas while the two capacitor plates and a portion of the first reaction tube are submersed in the liquid coolant.

In one embodiment, an external plasma system may be used for concurrently or simultaneously generating one or more reactive gases in a single reaction tube or in multiple separate reaction tubes, which may be completely or partially submersed in a liquid coolant. In one example, a first reaction tube of the one or more reaction tubes may be used for generating a first plasma and a second reaction tube of the one or more reaction tubes may be used for generating a second plasma different from the first plasma. In some cases, both the first reaction tube and the second reaction tube may be arranged in an opening between the ends of a C-shaped magnetic core. In other cases, the first reaction tube may be arranged in an opening between the ends of a C-shaped magnetic core and the second reaction tube may be arranged between two capacitor plates. In this case, a first plasma may be generated within the first reaction tube using the C-shaped magnetic core and a second plasma different from the first plasma may be generated within the second reaction tube using the two capacitor plates.

A shaped magnetic core wrapped with an inductive coil may comprise an inductive circuit for coupling electromagnetic energy into a gas. A capacitor may comprise a capacitive circuit for coupling electromagnetic energy into a gas. An energy coupling circuit for coupling electromagnetic energy into a gas may include an inductive circuit or a capacitive circuit. For example, the energy coupling circuit may comprise a capacitor or a magnetic coil (or electromagnetic coil).

In some embodiments, a plasma system may generate a plasma within a first reaction tube while the first reaction tube is submersed within a liquid coolant. To generate the plasma, a first gas may be inserted into the first reaction tube while one or more energy coupling circuits are used to couple electromagnetic energy into the first gas while the one or more energy coupling circuits are submersed within the liquid coolant. In one example, a first energy coupling circuit (e.g., a capacitive circuit) may be used as an ignition circuit for igniting the plasma and a second energy coupling circuit (e.g., an inductive circuit) may be used to maintain the plasma. The first energy coupling circuit may couple electromagnetic energy into the first gas during a first period of time and the second energy coupling circuit may couple electromagnetic energy into the first gas during a second period of time subsequent to the first period of time. In some cases, both the first energy coupling circuit and the second energy coupling circuit may couple electromagnetic energy into the first gas simultaneously.

In some cases, the external plasma system may include a replaceable tube assembly with an identifying interlock mechanism that prohibits the operation of the plasma system in the event that an authorized gas tube assembly is not present. In one example, an RFID tag associated with an authorized gas tube assembly or attached to an authorized gas tube may be used to identify the gas tube as compliant with the external plasma system. In the event that an authorized gas tube is present, the external plasma system may operate to generate a plasma using the authorized gas tube. On the other hand, if an unauthorized gas tube is present within the system, the system may be disabled or otherwise not able to generate a plasma using the unauthorized gas tube.

In some cases, the external plasma system may include a liquid level sensor that may be used to detect that a sufficient amount of liquid coolant is within a chamber before generating a plasma and/or operating the external plasma system. The external plasma system may also include an external ignition source located outside of the chamber in order to ignite gases within a reaction tube during plasma generation. The external plasma system may also include a light detector, light sensor, or spectrum analyzer for detecting when a plasma is being generated within a reaction tube. The light frequencies detected within a reaction tube may be used to identify the type of plasma being generated and to determine whether the desired plasma is being generated within the reaction tube. In some cases, in response to detecting that the desired plasma is not being generated within the reaction tube (e.g., based on not detecting the correct range of light frequencies being emitted), control circuitry for controlling an energy coupling circuit for generating the plasma may cause a frequency and/or an amplitude of an electrical signal driving the energy coupling circuit to be automatically adjusted. In one example, the control circuitry for controlling the energy coupling circuit may increase the frequency and/or the amplitude of the electrical signal driving the energy coupling circuit by a threshold amount until the desired plasma is generated.

In some cases, a secondary containment for the external plasma system may be required to include a gas purge or exhaust system.

In another embodiment, the external plasma system may generate a plasma for use in a variety of semiconductor process applications, such as Chemical Vapor Deposition (CVD), Plasma Enhanced Chemical Vapor Deposition (PE-CVD), Chemical Gas Etch, Plasma Enhanced Etch, Plasma Enhanced Physical Vapor Deposition (PE-PVD), Atomic Layer Deposition (ALD), and process chamber cleaning. In one example, the external plasma system may be connected to a process chamber for running the process chamber clean. In this case, a first gas (e.g., Argon gas) may injected into a process tube and then a second gas (NF3) may be added to perform the chamber clean process for a wide variety of materials. In another example, the external plasma system may be used for deposition of multiple reactants where one or more of the reactants are combined or mixed in the same process tube or in separate process tubes where the reactants combine in an activated state in a surface or gas phase reaction above the substrate.

In another embodiment, the external plasma system may be used for reducing greenhouse gas emissions (e.g., PFC abatement) by using the system in an exhaust manifold in which PFC elements are destroyed before sending them into the atmosphere or other abatement system. In another embodiment, the external plasma system may be used for atmospheric plasma processing to clean or treat surfaces and destroy films or cure them.

In another embodiment, the external plasma system may be used for powering an electromagnetic engine that may work in conjunction with or replace a combustion engine for powering various vehicles, such as in automobiles, cars, boats, airplanes, and helicopters.

The benefits of the plasma system include low cost, low maintenance clean and green technology. The external plasma system may provide improved semiconductor yields because the remote reaction enables neutrals to enter a semiconductor chamber and react without atomic level sputtering effects found in direct plasma processes. The external plasma system may reduce manufacturing costs through productivity improvements, reducing process times, and eliminating the need for additional process steps or other sequences of operation while also reducing material consumption costs. The external plasma system may be designed to be field serviceable, which may improve factory efficiencies and eliminate the wasteful process of removing parts or tubes from the production tool and shipping it to the original manufacturer for repair. The process of removing and shipping for repair is expensive and inefficient for production operations.

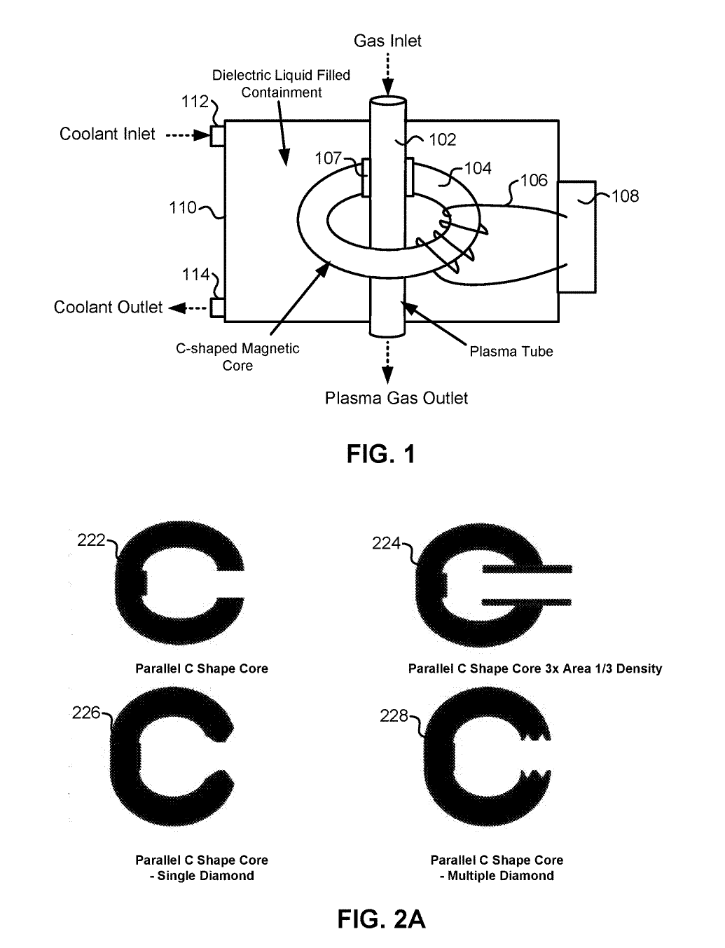

FIG. 1 depicts one embodiment of an external plasma system. The external plasma system may include internal components (e.g., a process tube and/or magnetic core) that are partially or completely submerged in a liquid coolant, such as a dielectric liquid coolant, glycol, ethylene glycol, propylene glycol, a PFC-based coolant, or liquid polytetrafluoroethylene (PTFE), in order to reduce the component failure rates of the internal components due to overheating. As depicted, the external plasma system includes a chamber 110, a coolant inlet 112, a coolant outlet 114, a C-shaped magnetic core 104, a process tube 102 (or reaction tube) arranged within an opening of the C-shaped magnetic core 104 between the ends of the C-shaped magnetic core 104, and an RF source 108 that drives wire 106. The external plasma system may also include a resonant circuit with an external load or an RLC circuit not depicted that is located either within the chamber 110 or outside of the chamber 110 in order to improve power delivery and provide load balancing. Within the opening of the C-shaped magnetic core 104 may exist an open space or a ceramic buffer material 107 that is arranged between the ends of the C-shaped magnetic core 104 and the process tube 102. In some cases, the ends of the C-shaped magnetic core 104 may directly abut or contact the process tube 102. The C-shaped magnetic core 104 may comprise a ferromagnetic material or a ferromagnetic metal. The chamber 110 may be filled with a liquid coolant. The RF source 108 drives the wire 106 that forms a coil surrounding the C-shaped magnetic core 104 and/or forms a primary winding for the C-shaped magnetic core 104. The RF source 108 may include a signal driver, a memory, and control circuitry for controlling the signal driver. The wire 106 may be connected to the chamber 110, which may be grounded. The process tube 102 may comprise metallic or dielectric materials or a combination of both. A plasma may be generated within the process tube 102 while a portion of the process tube 102 and the C-shaped magnetic core 104 are submerged within a liquid coolant. The plasma may be generated by injecting a first gas (e.g., Argon gas or NF3) into the process tube 102 and then coupling electromagnetic energy into the plasma via electromagnetic induction from the RF source 108 and the wire 106 wrapped around a portion of the C-shaped magnetic core 104.

In one embodiment, an external plasma system may include one or more process tubes arranged inside of a magnetic core that is shaped as a toroid or a doughnut-shaped object. In this case, a cylindrical process tube of the one or more process tubes may pass through a center of the doughnut-shaped magnetic core. In another embodiment, an external plasma system may include one or more process tubes arranged between the ends of a C-shaped magnetic core. In one example, a C-shaped magnetic core may be formed by cutting open a toroid-shaped magnetic core to form a “C” shape. The ends of the C-shaped magnetic core may be customized or configured (e.g., by forming pointed ends) in order to focus magnetic field energy to a localized region within an opening of the C-shaped magnetic core between the ends of the C-shaped magnetic core. The one or more process tubes may be positioned within the localized region within the opening of the C-shaped magnetic core.

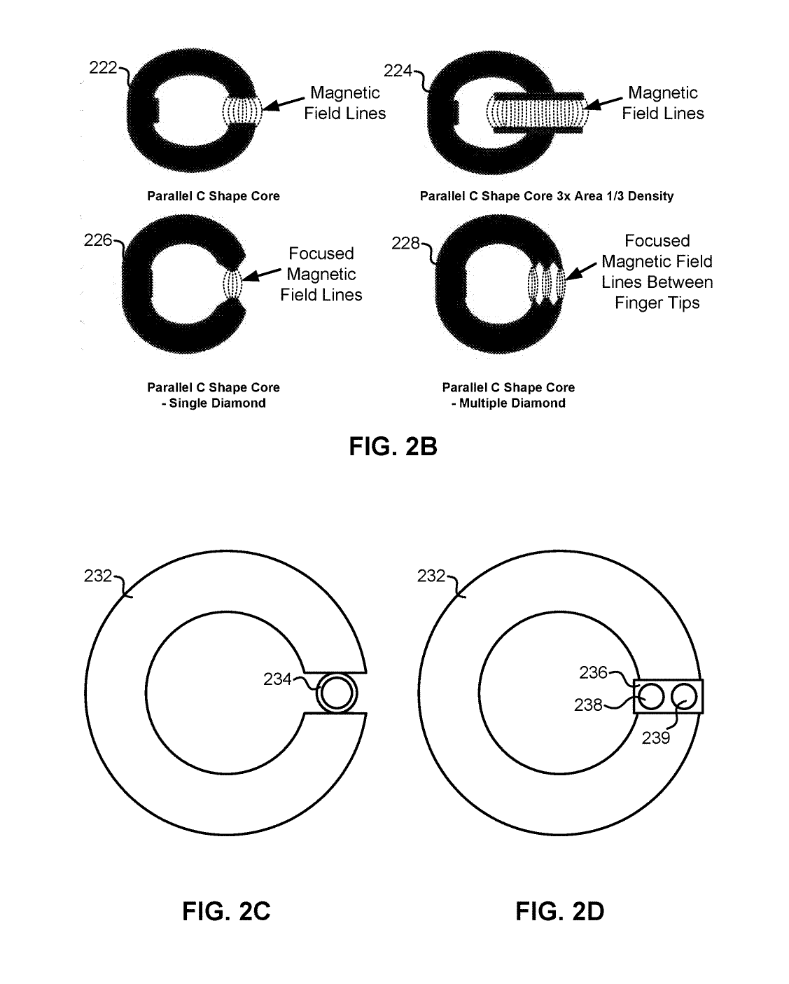

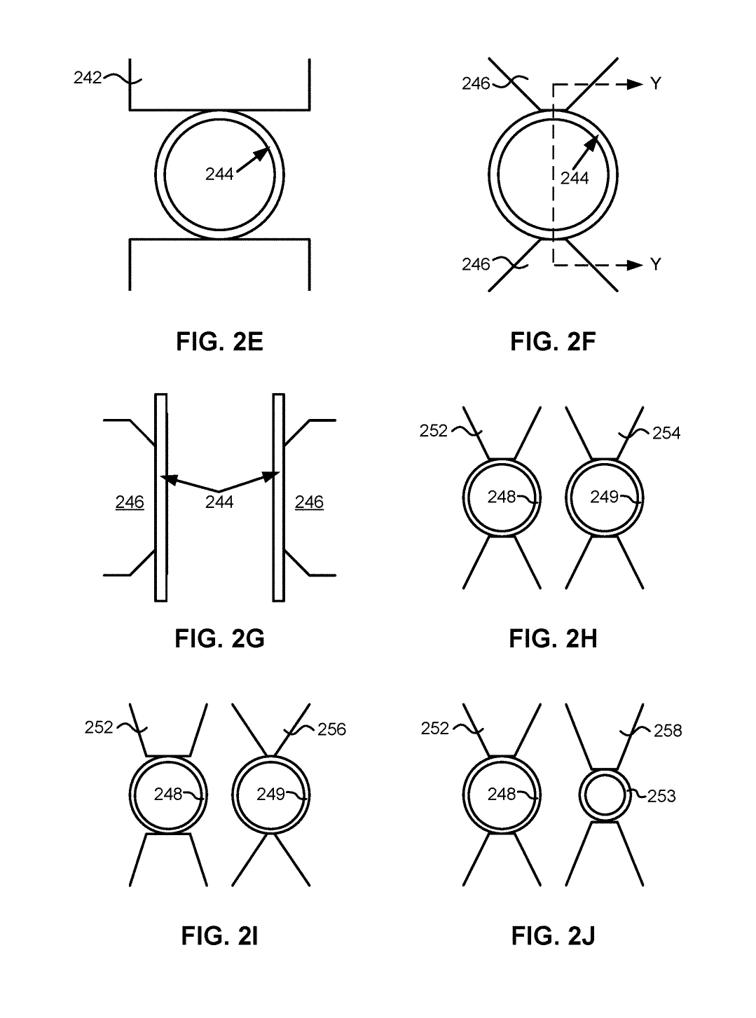

FIG. 2A depicts various embodiments of a C-shaped magnetic core, such as the C-shaped magnetic core 104 in FIG. 1. The embodiments include the parallel C-shaped magnetic core 222, the parallel C-shaped magnetic core 224 with an increased area between the ends of the C-shaped core, the C-shaped magnetic core 226 with pointed ends, and the C-shaped magnetic core 228 with multiple pointed ends (e.g., three finger pairs comprising three fingers from a top end of the C-shaped magnetic core aligned with three fingers from a bottom end of the C-shaped magnetic core). One or more process tubes, such as process tube 102 in FIG. 1, may be arranged within the openings of the C-shaped magnetic cores depicted in FIG. 2A. In one embodiment, a plurality of finger pairs may be formed at the ends of a C-shaped magnetic core. In one example, a first pointed end pair of the plurality of finger pairs (e.g., a top pointed end and a bottom pointed end aligned with the top pointed end) may be formed in order to focus magnetic field energy into a process tube positioned between the first pointed end pair.

FIG. 2B depicts the various embodiments of the C-shaped magnetic cores in FIG. 2A with exemplary magnetic field lines within the openings of the C-shaped magnetic cores. The C-shaped magnetic core 226 with pointed ends may cause the magnetic field lines to be focused between the pointed ends, which may allow increased energy to be coupled into the plasma within a process tube arranged within the opening. The C-shaped magnetic core 228 with multiple pointed ends may cause the magnetic field lines to be focused between the multiple pointed ends. In this case, three separate process tubes may be arranged within the opening of the C-shaped magnetic core 228 and positioned such that the three sets of focused magnetic field lines intersect the three separate process tubes.

FIG. 2C depicts one embodiment of a top plan view of a C-shaped magnetic core 232, such as the C-shaped magnetic core 104 in FIG. 1. As depicted, a process tube 234 has been arranged within the opening between the ends of the C-shaped magnetic core. The process tube 234 may comprise a ceramic or quartz material. The process tube arranged within the opening may comprise a cylindrical tube or a rectangular tube.

FIG. 2D depicts one embodiment of a top plan view of a C-shaped magnetic core 232, such as the C-shaped magnetic core 104 in FIG. 1. As depicted, a first process tube 238 and a second process tube 239 have been arranged within the opening between the ends of the C-shaped magnetic core. The process tubes may comprise ceramic or quartz materials. In some cases, the first process tube 238 and the second process tube 239 may be formed within a single block 236. The block 236 may comprise a ceramic block that includes two holes extending through the block. A first gas may be injected into a first hole of the two holes in order to generate a first plasma and a second gas may be injected into a second hole of the two holes in order to generate a second plasma different from the first plasma. Although cylindrical holes have been depicted in FIG. 2D, other hole shapes may also be used, such as rectangular holes cut into and extending through the block. In some cases, a block, such as block 236, may include a plurality of holes extending through the block corresponding with a plurality of process tubes.

FIG. 2E depicts one embodiment of an opening between the ends of a C-shaped magnetic core. As depicted, a single process tube 244 may be arranged within the opening with non-pointed ends 242. FIG. 2F depicts another embodiment of an opening between the ends of a C-shaped magnetic core. As depicted, a single process tube 244 is arranged within the opening with pointed ends 246. The pointed ends 246 may focus the magnetic field energy between the pointed ends 246 and improve the coupling of electromagnetic energy into the plasma within the process tube 244. FIG. 2G is one example of a cross-sectional view taken along line Y-Y of FIG. 2F. In this case, FIG. 2F may comprise a top-down view looking down into the cylinder and FIG. 2G may comprise a side view of the cylinder. As depicted, the ends of the C-shaped magnetic core may also be tapered in the top-down direction (Z direction) in order to focus magnetic field energy between the pointed ends 246.

FIG. 2H depicts one embodiment of an opening between the ends of a C-shaped magnetic core in which a first process tube 248 and a second process tube 249 have been positioned. In this case, two different plasmas may be generated using the two process tubes and a common C-shaped magnetic core that is shared by the two process tubes. The pointed end 252 may focus magnetic field energy into the first process tube 248 and the pointed end 254 may focus magnetic field energy into the second process tube 249. FIG. 2I depicts one embodiment of an opening between the ends of a C-shaped magnetic core in which a first process tube 248 and a second process tube 249 have been positioned. In this case, the pointed end 256 has a sharper angle or a sharper point than the pointed end 252. The degree of pointedness or the shape of the pointed ends may be customized based on the position of a process tube with respect to a C-shaped magnetic core. In one example, the second process tube 249 may comprise an outer process tube (i.e., a process tube that is farthest from the center of the C-shaped magnetic core) and the first process tube 248 may comprise an inner process tube (i.e., a process tube that is closest to the center of the C-shaped magnetic core). In another example, the second process tube 249 may comprise an inner process tube and the first process tube 248 may comprise an outer process tube. FIG. 2J depicts one embodiment of an opening between the ends of a C-shaped magnetic core in which a first process tube 248 and a third process tube 253 have been positioned. The size or diameter of the third process tube 253 may be smaller than the size or diameter of the first process tube 248. In this case, the pointed end 258 may extend farther into the opening than the pointed end 252 in order to make contact with the third process tube 253.

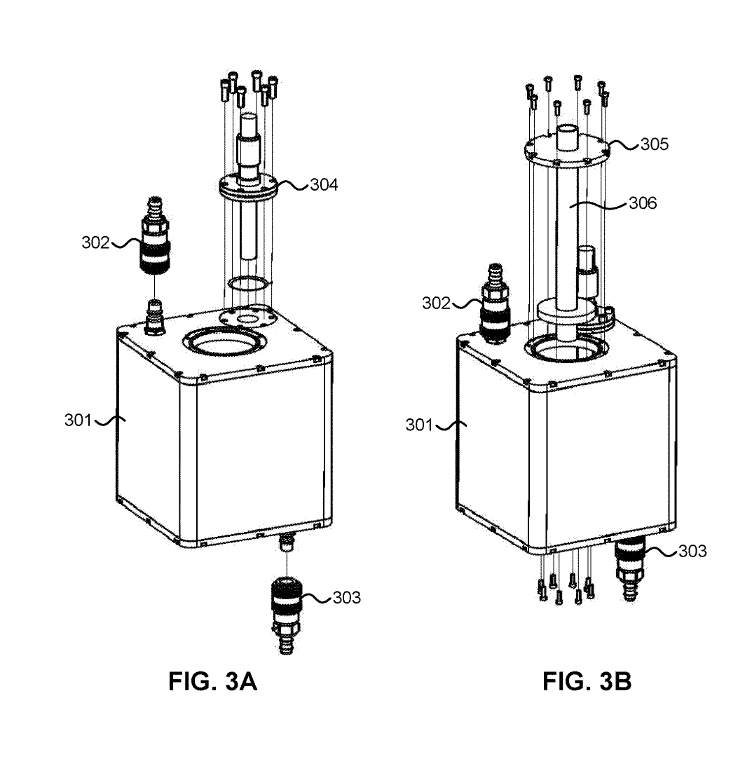

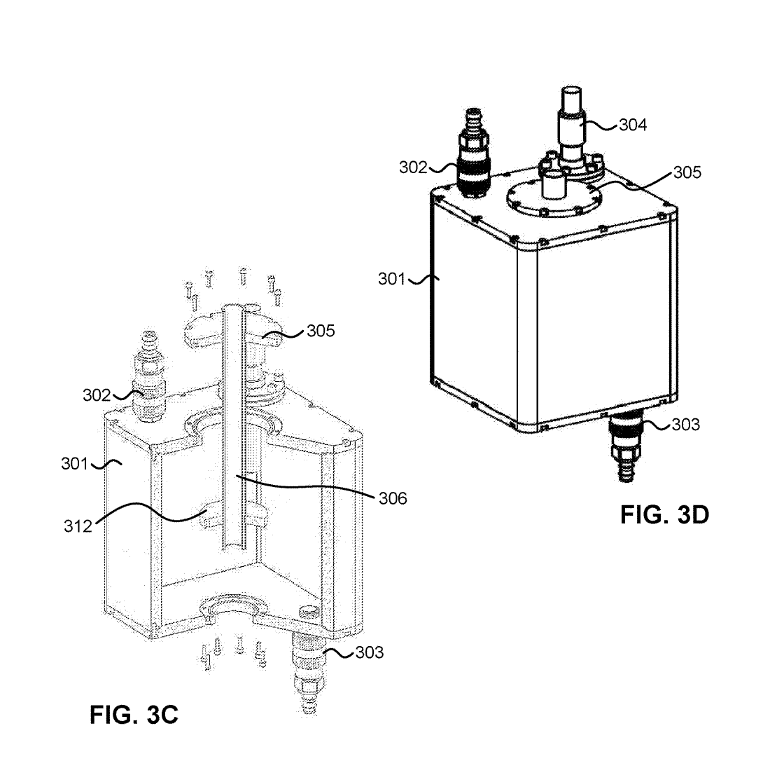

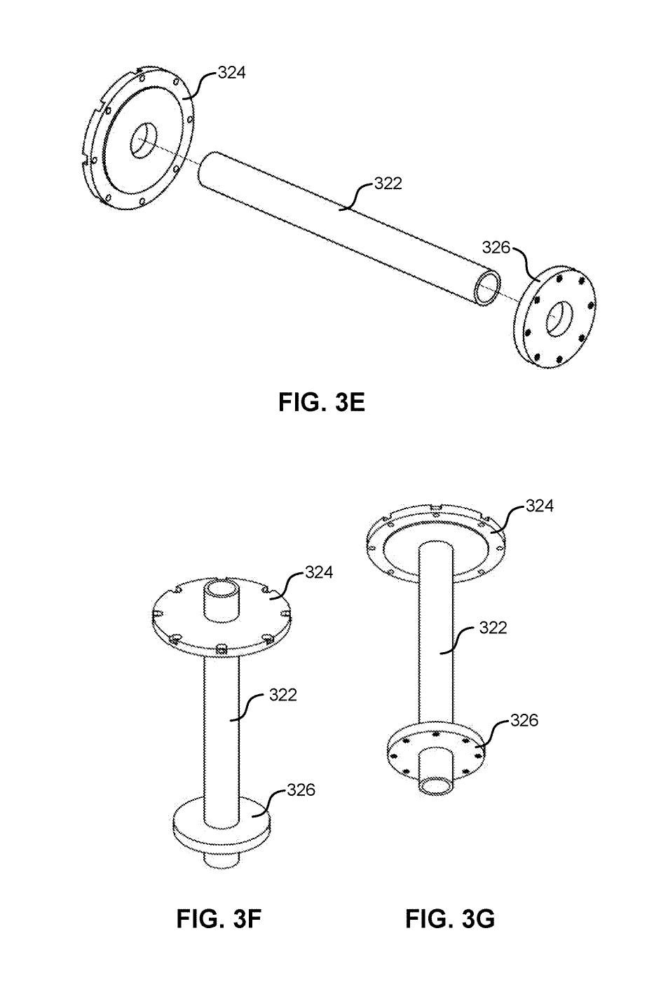

FIGS. 3A-3D depict one embodiment of a portion of an external plasma system including a chamber for submersing a process tube and one or more energy coupling circuits (e.g., an electromagnetic coil and a capacitor) in a liquid coolant while a plasma is generated within the process tube. As depicted, the external plasma system includes a chamber 301 (e.g., an 8″×8″ square chamber), a coolant inlet connector 302, a coolant outlet connector 303, an RF source assembly 304, and a process tube assembly that includes a process tube 306 and a top plate 305 attached to the process tube 306. A magnetic core 312 (e.g., a C-shaped magnetic core or ring-shaped magnetic core) may be positioned within the chamber 301. The magnetic core 312 may be positioned within the chamber 301 using a plastic support structure not depicted within the chamber 301. In the case that the magnetic core 312 comprises a toroid-shaped core (or ring-shaped core), the process tube 306 may be arranged inside of the magnetic core 312. In the case that the magnetic core 312 comprises a C-shaped magnetic core, the process tube 306 may be arranged between the ends of the C-shaped magnetic core. One benefit of arranging the process tube 306 to be between the ends of the C-shaped magnetic core is that the magnetic field intensity may be increased and a greater amount of electromagnetic energy may be coupled into a plasma generated within the process tube 306. FIGS. 3E-3G depict one embodiment of a process tube assembly that includes a process tube 322 arranged between a top plate 324 and a bottom plate 326. In one example, the process tube 322 may have a 1 inch diameter, the top plate 324 may have a 4 inch diameter, and the bottom plate 326 may have a 2.8 inch diameter.

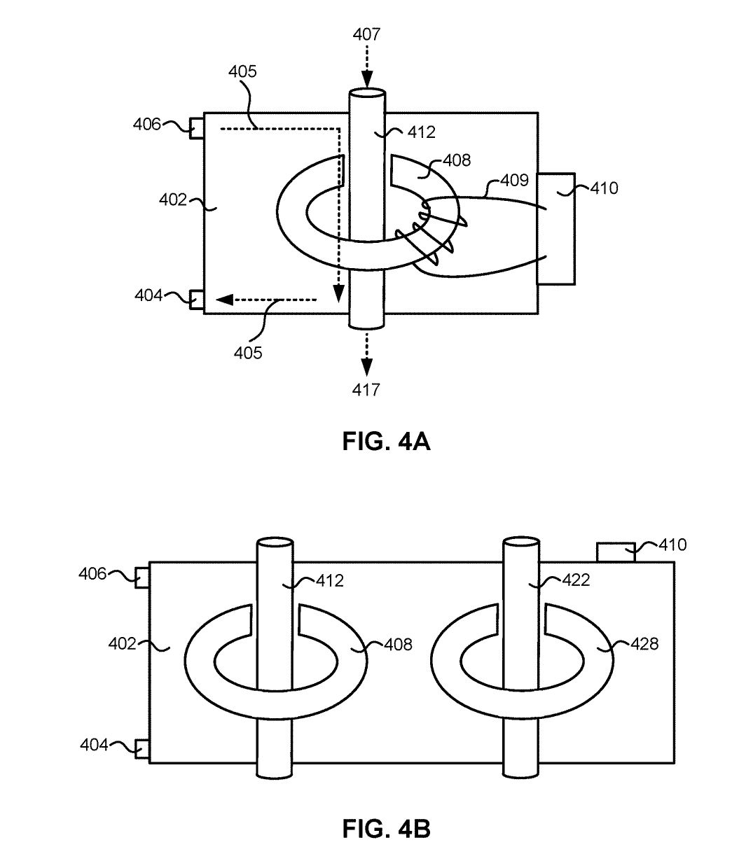

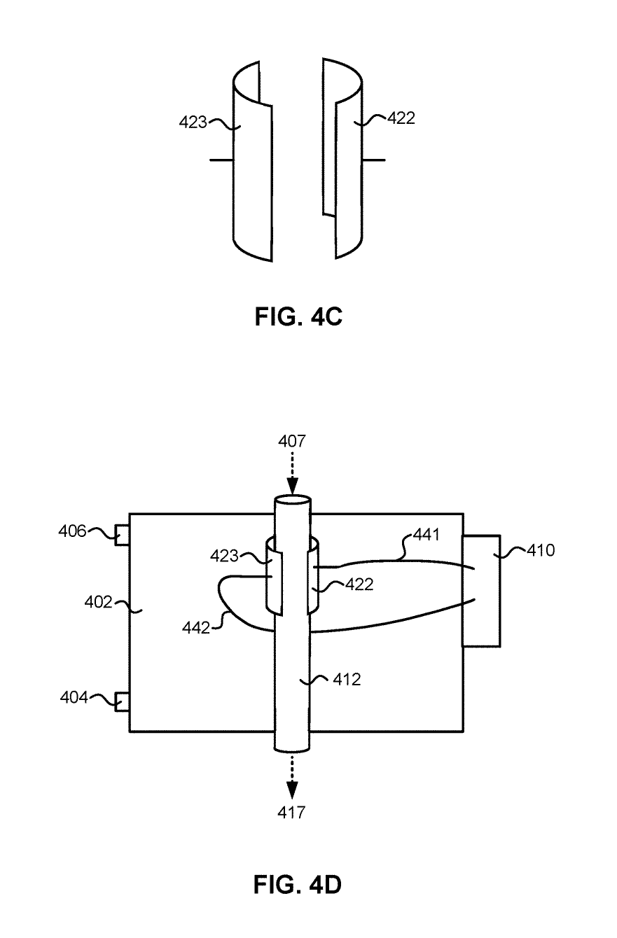

FIG. 4A depicts one embodiment of an external plasma system. The external plasma system includes a chamber 402, a coolant inlet 406, a coolant outlet 404, an RF source 410, a process tube 412, and a C-shaped magnetic core 408. A liquid coolant may be injected into the coolant inlet 406 and follow the coolant flow 405 into the chamber 402. In some cases, the coolant flow 405 may enter the chamber 402 at the coolant inlet 406, be directed to be substantially parallel to the process tube 412, and then exit the coolant outlet 404. In some cases, the coolant flow may be designed such that forced convection occurs within the chamber 402 to remove heat from the process tube 412 and the C-shaped magnetic core 408. As depicted, a first gas 407 may be inserted into the process tube 412 and a first plasma 417 may be generated and outputted from the process tube 412.

In one embodiment, the first gas 407 may be inserted or injected into the process tube 412 while the RF source 410 drives a wire 409 that forms a coil surrounding a portion of the C-shaped magnetic core 408 to couple electromagnetic energy into the first gas 407 within the process tube 412. In this case, the first plasma 417 may be generated within the process tube 412 by coupling electromagnetic energy into the first gas 407 while the C-shaped magnetic core 408 and a portion of the process tube 412 positioned between the ends of the C-shaped magnetic core 408 are submersed in a liquid coolant.

In some cases, the RF source 410 may include a signal driver for driving the wire 409, control circuitry for controlling the signal driver, a memory (e.g., a non-volatile semiconductor memory), and one or more processors in communication with the control circuitry for executing instructions stored in the memory. The RF source 410 may include a direct current (DC) and/or alternating current (AC) signal generator. The RF source 410 may be used to drive the wire 409 to ignite a plasma within the process tube 412 or to maintain the plasma. The RF source 410 may set or adjust the electrical signals driven on the wire 409 depending on the type of plasma to be generated within the process tube 412 and/or the time duration during which a plasma has been generated within the process tube 412. In some cases, the operating frequency range of the RF source 410 may range between 40 kHz and 40 MHz. For example, the frequency of the electrical signal applied to the wire 409 may be 2 MHz, 13.56 MHz, or 27.12 MHz. The RF source 410 may alter the frequency and/or amplitude of the electrical signal applied to wire 409 during operation in order to react to changing characteristics of the plasma being generated and to ensure that power remains stable during the operation.

FIG. 4B depicts an alternative embodiment of an external plasma system. The external plasma system includes a chamber 402, a coolant inlet 406, a coolant outlet 404, an RF source 410, a first process tube 412, a first C-shaped core 408, a second process tube 422, and a second C-shaped core 428. A first gas may be inserted into the first process tube 412 and a first plasma may be generated and outputted from the first process tube 412. A second gas may be inserted into the second process tube 422 and a second plasma may be generated and outputted from the second process tube 422. The first plasma and the second plasma may both be generated at the same time or concurrently.

In some cases, a first signal of a first frequency may be applied to the first C-shaped core 408 and a second signal of a second frequency different from the first frequency may be applied to the second C-shaped core 428 from the RF source 410. In one example, the first frequency (e.g., 13.56 MHz) may be a higher frequency than the second frequency (e.g., 450 kHz). A second RF source may also be used to power the second C-shaped core 428 while the RF source 410 is used to power the first C-shaped core 408. In some cases, the number of coil windings around the first C-shaped core 408 may be the same as or different from the number of coil windings around the second C-shaped core 428. One benefit of arranging two or more process tube assemblies within a common chamber is that two or more different plasmas may be generated at the same time or at different times.

FIG. 4C depicts one embodiment of a capacitor. The capacitor includes a first plate 423 and a second plate 422. The capacitor plates or electrodes may comprise a metal, metal alloy, or a combination of metals, such as aluminum, copper, silver, nickel, or gold.

FIG. 4D depicts one embodiment of an external plasma system. The external plasma system includes a chamber 402, a coolant inlet 406, a coolant outlet 404, an RF source 410, a process tube 412, and a capacitor comprising two plates 422-423 surrounding a portion of the process tube 412. A liquid coolant may be injected into the coolant inlet 406 and follow a coolant flow within the chamber 402 that enables forced convection to occur within the chamber 402 to remove heat from the process tube 412. As depicted, a first gas 407 may be inserted into the process tube 412 and a first plasma 417 may be generated and outputted from the process tube 412.

In one embodiment, the first gas 407 may be inserted or injected into the process tube 412 while the RF source 410 drives wires 441-442. The wire 441 may be connected to capacitor plate 422 and the wire 442 may be connected to capacitor plate 423. In this case, the first plasma 417 may be generated within the process tube 412 by coupling electromagnetic energy into the first gas 407 via the capacitor plates 422-423 while the capacitor plates 422-423 and a portion of the process tube 412 are submersed in a liquid coolant.

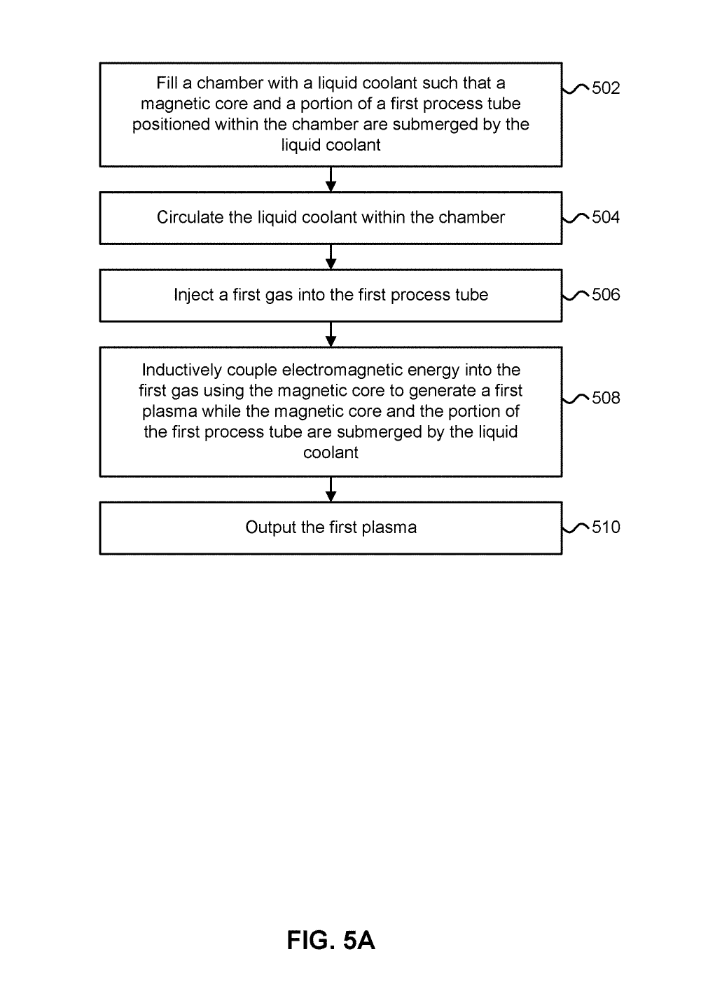

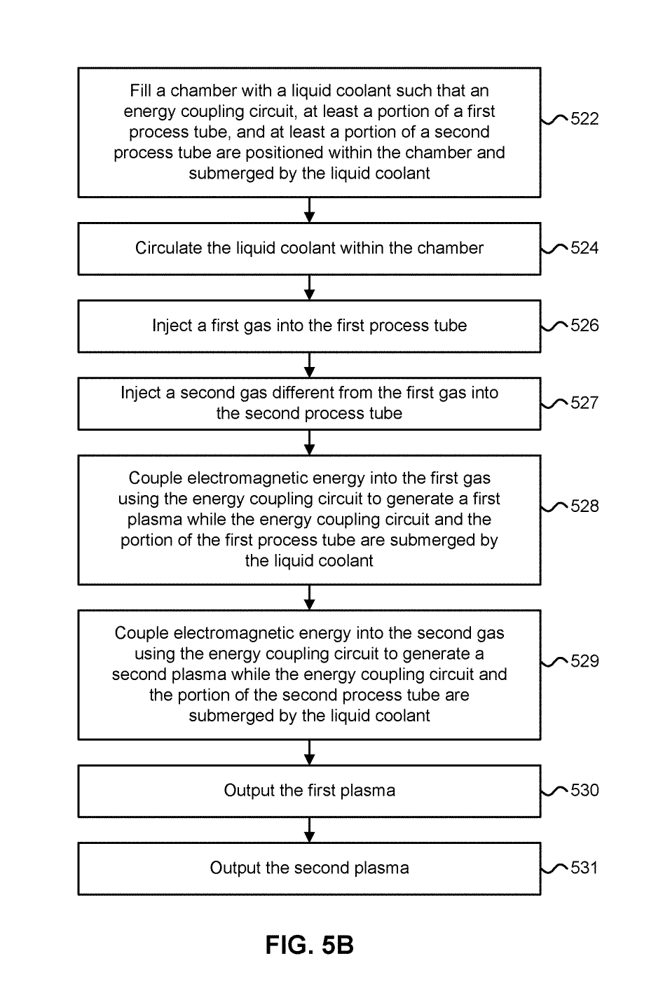

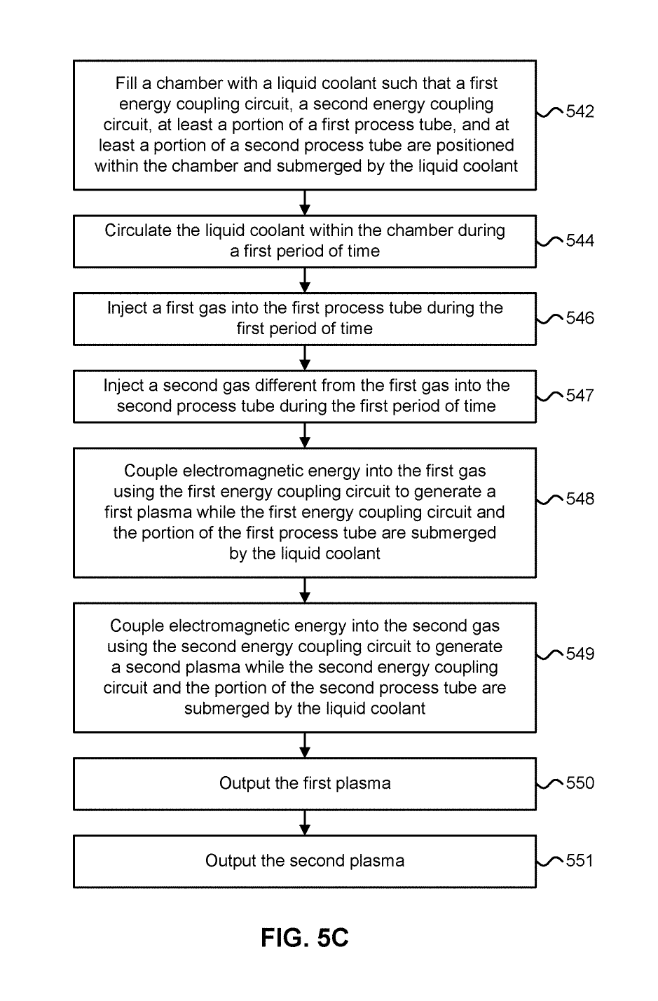

FIG. 5A is a flowchart describing one embodiment of a process for generating a plasma using an external plasma system. In one embodiment, the process of FIG. 5A may be performed by an external plasma system, such as the external plasma systems depicted in FIGS. 1, 4A-4B, and 4D.

In step 502, a chamber is filled with a liquid coolant such that a magnetic core and a portion of a first process tube positioned within the chamber are submersed within the liquid coolant. The magnetic core may comprise a C-shaped magnetic core. In step 504, the liquid coolant is circulated within the chamber. The liquid coolant may be circulated within the chamber such that forced convection occurs to remove heat from the first process tube and the magnetic core during operation of the external plasma system. In step 506, a first gas is injected into the first process tube. The first gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}). In step 508, electromagnetic energy is inductively coupled into the first gas using the magnetic core to generate a first plasma while the magnetic core and a portion of the first process tube are submersed within liquid coolant. In one embodiment, the first plasma may be generated within the first process tube by coupling energy derived from an RF source into the first gas using a C-shaped magnetic core while the C-shaped magnetic core and a portion of the first process tube positioned between the ends of the C-shaped magnetic core are submersed in the liquid coolant. In step 510, the first plasma is outputted. In one example, the first plasma may be outputted and used for semiconductor processing applications, such as a deposition step or process chamber cleaning.

FIG. 5B is a flowchart describing another embodiment of a process for generating a plasma using an external plasma system. In one embodiment, the process of FIG. 5B may be performed by an external plasma system, such as the external plasma systems depicted in FIGS. 1, 4A-4B, and 4D.

In step 522, a chamber is filled with a liquid coolant such that an energy coupling circuit, at least a portion of a first process tube, and at least a portion of a second process tube are positioned within the chamber and submerged by the liquid coolant. In one embodiment, the energy coupling circuit may comprise a magnetic core or an electromagnetic coil. In another embodiment, the energy coupling circuit may comprise a capacitor. The capacitor may comprise metal plates that are clamped to a portion of a process tube, such as the first process tube. The capacitor may comprise electrodes that are deposited or electroplated onto a surface of a process tube. The electroplating may form two metal layers on the surface of the process tube corresponding with two capacitor plates.

In step 524, the liquid coolant is circulated within the chamber. In step 526, a first gas is injected into the first process tube. The first gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}). In step 527, a second gas different from the first gas is injected into the second process tube. The second gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}).

In step 528, electromagnetic energy is coupled into the first gas using the energy coupling circuit to generate a first plasma while the energy coupling circuit and the portion of the first process tube are submerged by the liquid coolant. In step 529, electromagnetic energy is coupled into the second gas using the energy coupling circuit to generate a second plasma while the energy coupling circuit and the portion of the second process tube are submerged by the liquid coolant. In step 530, the first plasma is outputted. In step 531, the second plasma is outputted.

In one embodiment, the first process tube and the second process tube may be arranged in an opening between the ends of a C-shaped magnetic core. In another embodiment, the first process tube and the second process tube may be arranged between two capacitor plates. In these cases, the same energy coupling circuit may be used to generate, ignite, or produce two different plasmas at the same time.

FIG. 5C is a flowchart describing an alternative embodiment of a process for generating one or more plasmas using an external plasma system. In one embodiment, the process of FIG. 5C may be performed by an external plasma system, such as the external plasma systems depicted in FIGS. 1, 4A-4B, and 4D.

In step 542, a chamber is filled with a liquid coolant such that a first energy coupling circuit, a second energy coupling circuit, at least a portion of a first process tube, and at least a portion of a second process tube are positioned within the chamber and submerged by the liquid coolant. The liquid coolant may comprise a heat transfer liquid, a dielectric liquid coolant, or a non-dielectric liquid coolant. The liquid coolant may include, for example, glycol, ethylene glycol, propylene glycol, a PFC coolant, or liquid polytetrafluoroethylene (PTFE). In one example, the liquid coolant may be operated within a range between −50 degrees Celsius and +50 degrees Celsius.

In step 544, the liquid coolant is circulated within the chamber during a first period of time. The liquid coolant may be circulated within the chamber such that forced convection occurs to remove heat from both the first process tube and the second process tube during operation of the external plasma system. In step 546, a first gas is injected into the first process tube during the first period of time. In step 547, a second gas different from the first gas is injected into the second process tube during the first period of time. The first gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}). The second gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}).

In step 548, electromagnetic energy is coupled into the first gas using the first energy coupling circuit to generate a first plasma while the first energy coupling circuit and the portion of the first process tube are submerged by the liquid coolant. In step 549, electromagnetic energy is coupled into the second gas using the second energy coupling circuit to generate a second plasma while the second energy coupling circuit and the portion of the second process tube are submerged by the liquid coolant. In one embodiment, the first energy coupling circuit may comprise a first magnetic core or a first electromagnetic coil and the second energy coupling circuit may comprise a second capacitor. In another embodiment, both the first energy coupling circuit and the second energy coupling circuit may comprise electromagnetic coils. In another embodiment, the first energy coupling circuit may comprise a capacitor. The capacitor may comprise metal plates that are clamped to a portion of the first process tube. The capacitor may comprise electrodes that are deposited or electroplated onto a surface of the first process tube. The electroplating may form two separated metal layers on the surface of the first process tube corresponding with two capacitor plates. In step 550, the first plasma is outputted. In step 551, the second plasma is outputted. In some cases, the first plasma and the second plasma may be generated and outputted at the same time.

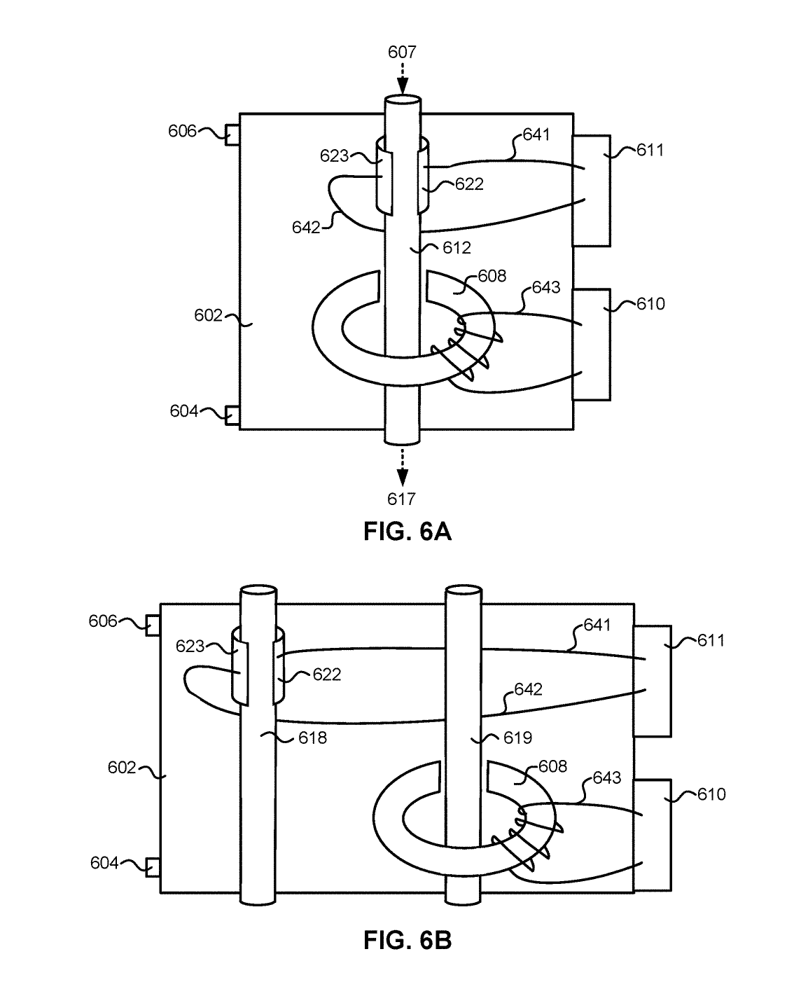

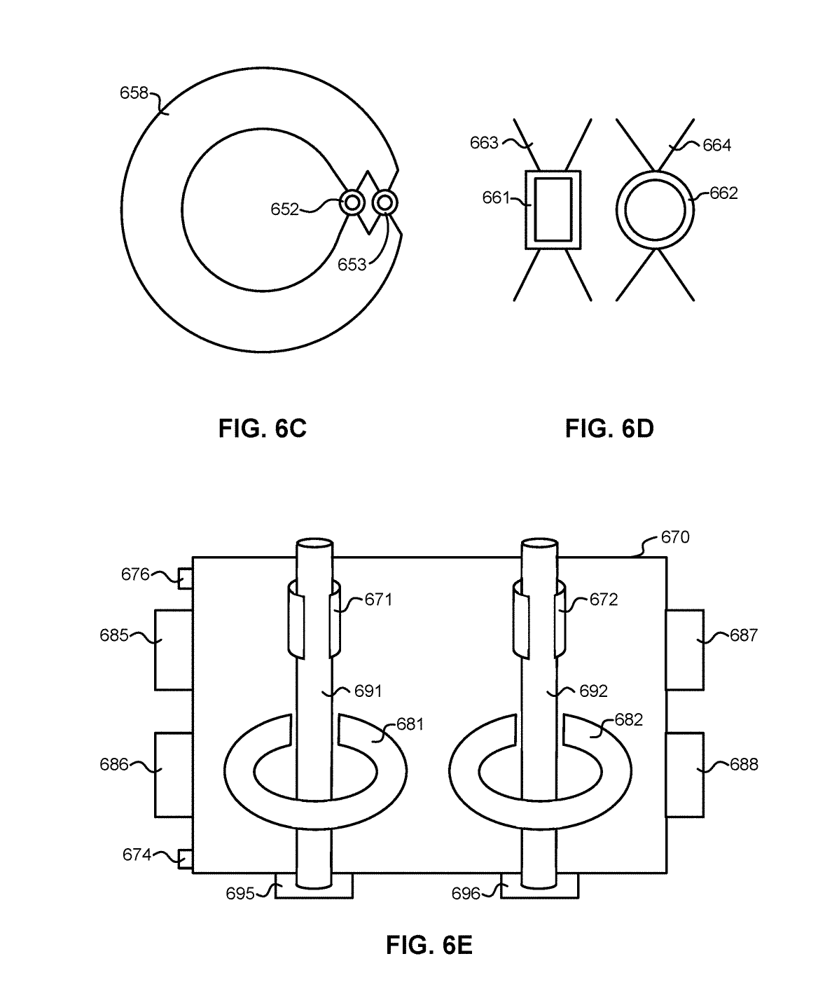

FIG. 6A depicts another embodiment of an external plasma system. As depicted, the external plasma system includes a chamber 602, a coolant inlet 606, a coolant outlet 604, a first RF source 610, a second RF source 611, a process tube 612, a first energy coupling circuit comprising a capacitor with plates 622-623, and a second energy coupling circuit comprising a magnetic core 608 with a wire 643 coiled around or surrounding the magnetic core 608. The magnetic core 608 may comprise a ferromagnetic material or a ferromagnetic metal. The chamber 602 may be filled with a liquid coolant, such as a dielectric liquid coolant, glycol, ethylene glycol, propylene glycol, a PFC-based coolant, or liquid polytetrafluoroethylene (PTFE). The RF source 611 drives wires 641-642 that are directly connected to capacitor plates 622-623. The RF source 610 drives the wire 643 that forms a coil surrounding the magnetic core 608 and/or forms a primary winding for the magnetic core 608. The RF sources 610-611 may include signal drivers, semiconductor memory, and/or control circuitry for controlling the signal drivers. It should be noted that although the first energy coupling circuit is depicted as being arranged above the second energy coupling circuit and positioned closer to the top of the chamber 602 in FIG. 6A, this spatial arrangement may be reversed such that the first energy coupling circuit is arranged below the second energy coupling circuit and positioned closer to the bottom of the chamber 602.

During operation of the external plasma system, a liquid coolant may be injected into the coolant inlet 606 and follow a coolant flow into the chamber 602 to the coolant outlet 604. In some cases, the coolant flow may be directed to be substantially parallel to the process tube 612 or be designed such that forced convection occurs within the chamber 602 to remove heat from the process tube 612. While forced convection is occurring within the chamber 602, a first gas 607 may be inserted into the process tube 612 and a first plasma 617 may be generated and outputted from the process tube 612.

In one embodiment, the first gas 607 may be inserted or injected into the process tube 612 while both the RF source 611 drives the wires 641-642 and the RF source 610 drives the wire 643 that forms a coil surrounding a portion of the magnetic core 608 to couple electromagnetic energy into the first gas 607 within the process tube 612. In this case, the first plasma 617 may be generated within the process tube 612 while both the first energy coupling circuit and the second energy coupling circuit are coupling electromagnetic energy into the first gas 607. Both the first energy coupling circuit and the second energy coupling circuit may be submersed within the liquid coolant along with the portions of the process tube 612 in which electromagnetic energy is being coupled.

In another embodiment, only one of the energy coupling circuits (e.g., only the first energy coupling circuit or the second energy coupling circuit) may be used to couple electromagnetic energy into the first gas 607 during a particular period of time. In one example, the first energy coupling circuit may be used to ignite the first plasma 617 during a first period of time and then the second energy coupling circuit may be used to maintain the first plasma 617 during a second period of time subsequent to the first period of time.

In other cases, the first energy coupling circuit may be used to generate a particular plasma within the process tube 612 during a first period of time and the second energy coupling circuit may be used to generate a second plasma different from the particular plasma within the process tube 612 during a second period of time subsequent to the first period of time.

In some cases, an RF source, such as RF source 610 or RF source 611, may include a signal driver, control circuitry for controlling the signal driver, a memory (e.g., a non-volatile semiconductor memory), and one or more processors in communication with the control circuitry for executing instructions stored in the memory. An RF source may include a direct current (DC) and/or alternating current (AC) signal generator. The RF source 611 may drive the wires 641-642 with a first signal of a first amplitude (e.g., 18V) and a first frequency (e.g., 2 MHz) while the RF source 610 drives the wire 643 with a second signal of a second amplitude (e.g., 5V) and a second frequency (e.g., 13.56 MHz). The RF sources 610-611 may set or adjust the electrical signals driven independently of each other over time and may adjust the electrical signals driven depending on the type of plasma to be generated within the process tube 612 and/or the time duration during which a plasma has been generated within the process tube 612.

FIG. 6B depicts an alternative embodiment of an external plasma system. The external plasma system includes a chamber 602, a coolant inlet 606, a coolant outlet 604, a first RF source 610, a second RF source 611, a first process tube 618, a second process tube 619, a first energy coupling circuit comprising a capacitor with plates 622-623, and a second energy coupling circuit comprising a magnetic core 608 with a wire 643 coiled around or surrounding the magnetic core 608. The magnetic core 608 may comprise a ferromagnetic material or a ferromagnetic metal. The chamber 602 may be filled with a liquid coolant, such as a dielectric liquid coolant, glycol, ethylene glycol, propylene glycol, a PFC-based coolant, or liquid polytetrafluoroethylene (PTFE). The RF source 611 drives wires 641-642 that are directly connected to capacitor plates 622-623. The RF source 610 drives the wire 643 that forms a coil surrounding the magnetic core 608.

In some cases, a first gas may be inserted into the first process tube 618 and a first plasma may be generated and outputted from the first process tube 618. A second gas may be inserted into the second process tube 619 and a second plasma may be generated and outputted from the second process tube 619. In one example, the first plasma and the second plasma may both be generated at the same time or concurrently. In another example, the first plasma and the second plasma may be generated at different times while the chamber 602 is filled with the same liquid coolant. One benefit of arranging two or more process tube assemblies within a common chamber is that two or more different plasmas may be generated at the same time or at different times.

FIG. 6C depicts one embodiment of a C-shaped magnetic core 658 with an opening between the ends of the C-shaped magnetic core 658 in which a first process tube 652 and a second process tube 653 have been positioned. In this case, two different plasmas may be generated using the two process tubes and the common C-shaped magnetic core 658 that is shared by the two process tubes. In one embodiment, a first capacitor may be coupled to the first process tube 652 and a second capacitor different from the first capacitor may be coupled to the second process tube 653. The first capacitor may be used for igniting a first plasma within the first process tube 652 and the second capacitor may be used for igniting a second plasma within the second process tube 653. The C-shaped magnetic core 658 may then be used to maintain the first plasma within the first process tube 652 and the second plasma within the second process tube 653. Thus, the first process tube 652 may be coupled with a first energy coupling circuit (e.g., the first capacitor) and a second energy coupling circuit (e.g., the C-shaped magnetic core 658) while the second process tube 653 may be coupled with a third energy coupling circuit (e.g., the second capacitor) and the second energy coupling circuit. The second energy coupling circuit may be shared by both the first process tube 652 and the second process tube 653.

FIG. 6D depicts one embodiment of an opening between the ends of a C-shaped magnetic core in which a first process tube 661 and a second process tube 662 have been positioned. The pointed end 663 may focus magnetic field energy into the first process tube 661 and the pointed end 664 may focus magnetic field energy into the second process tube 662. As depicted, the pointed end 664 has a sharper angle or a sharper point than the pointed end 663. The degree of pointedness or the shape of the pointed ends may be customized based on the position of a process tube with respect to a C-shaped magnetic core. In one example, the second process tube 662 may comprise an outer process tube (i.e., a process tube that is farthest from the center of the C-shaped magnetic core) similar to process tube 653 in FIG. 6C and the first process tube 661 may comprise an inner process tube (i.e., a process tube that is closest to the center of the C-shaped magnetic core) similar to process tube 652 in FIG. 6C.

In some cases, the first process tube 661 may be coupled with a first energy coupling circuit (e.g., a first capacitor comprising two electroplated plates on a surface of the first process tube) and a second energy coupling circuit (e.g., a shaped magnetic core) while the second process tube 662 may be coupled with a third energy coupling circuit (e.g., a second capacitor comprising two electroplated plates on a surface of the second process tube) and the second energy coupling circuit. The second energy coupling circuit may be shared by both the first process tube 661 and the second process tube 662.

FIG. 6E depicts another embodiment of an external plasma system. As depicted, the external plasma system includes a chamber 670, a coolant inlet 676, a coolant outlet 674, a first RF source 685, a second RF source 686, a third RF source 687, a fourth RF source 688, a first process tube 691, a second process tube 692, a first energy coupling circuit 671, a second energy coupling circuit 681, a third energy coupling circuit 672, a fourth energy coupling circuit 682, a first electromechanical actuator 695, and a second electromechanical actuator 696. The chamber 670 may be filled with a liquid coolant, such as a dielectric liquid coolant, glycol, ethylene glycol, propylene glycol, a PFC-based coolant, or liquid polytetrafluoroethylene (PTFE). The first RF source 685 may drive the first energy coupling circuit 671, the second RF source 686 may drive the second energy coupling circuit 681, the third RF source 687 may drive the third energy coupling circuit 672, and the fourth RF source 688 may drive the fourth energy coupling circuit 682. In some cases, the first electromechanical actuator 695 may control a rotation or an orientation of the first process tube 691 and the second electromechanical actuator 696 may control a rotation or an orientation of the second process tube 692.

During operation of the external plasma system, a first gas may be inserted or injected into the first process tube 691 while both the first RF source 685 and the second RF source 686 cause the first energy coupling circuit 671 and the second energy coupling circuit 681 to couple electromagnetic energy into the first gas. The first electromechanical actuator 695 may automatically rotate the first process tube 691 prior to or during operation in order to reduce or prevent plasma wear from affecting the first process tube 691. A second gas may be inserted or injected into the second process tube 692 while both the third RF source 687 and the fourth RF source 688 cause the third energy coupling circuit 672 and the fourth energy coupling circuit 682 to couple electromagnetic energy into the second gas. The second electromechanical actuator 696 may automatically rotate the second process tube 692 prior to or during operation in order to reduce or prevent plasma wear from affecting the second process tube 692.

In one embodiment, a first plasma may be generated within the first process tube 691 while both the first energy coupling circuit 671 and the second energy coupling circuit 681 couple electromagnetic energy into a first gas within the first process tube 691. Both the first energy coupling circuit 671 and the second energy coupling circuit 681 may be submersed within the liquid coolant along with the portions of the first process tube 691. In another embodiment, only one of the energy coupling circuits (e.g., only the first energy coupling circuit 671 or the second energy coupling circuit 681) may be used to couple electromagnetic energy into the first gas during a particular period of time. In one example, the first energy coupling circuit 671 may be used to ignite the first plasma during a first period of time and then the second energy coupling circuit 681 may be used to maintain the first plasma during a second period of time subsequent to the first period of time.

In some embodiments, the first energy coupling circuit 671 and the second energy coupling circuit 681 may be used to generate a first plasma within the first process tube 691 while the third energy coupling circuit 672 and the fourth energy coupling circuit 682 may be used to generate a second plasma different from the first plasma within the second process tube 692.

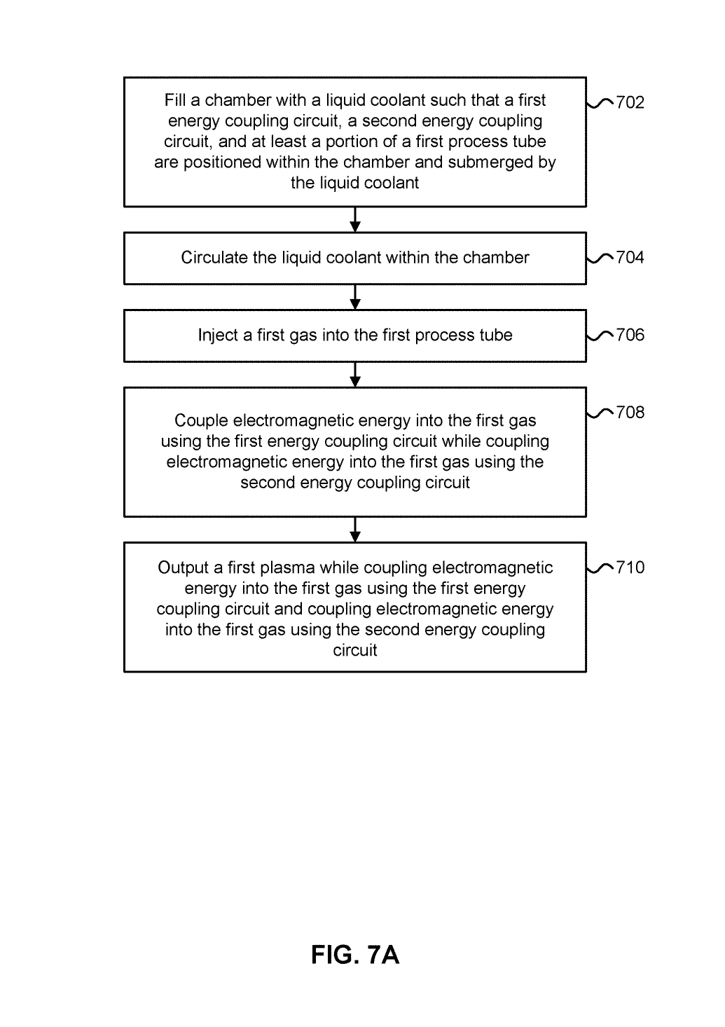

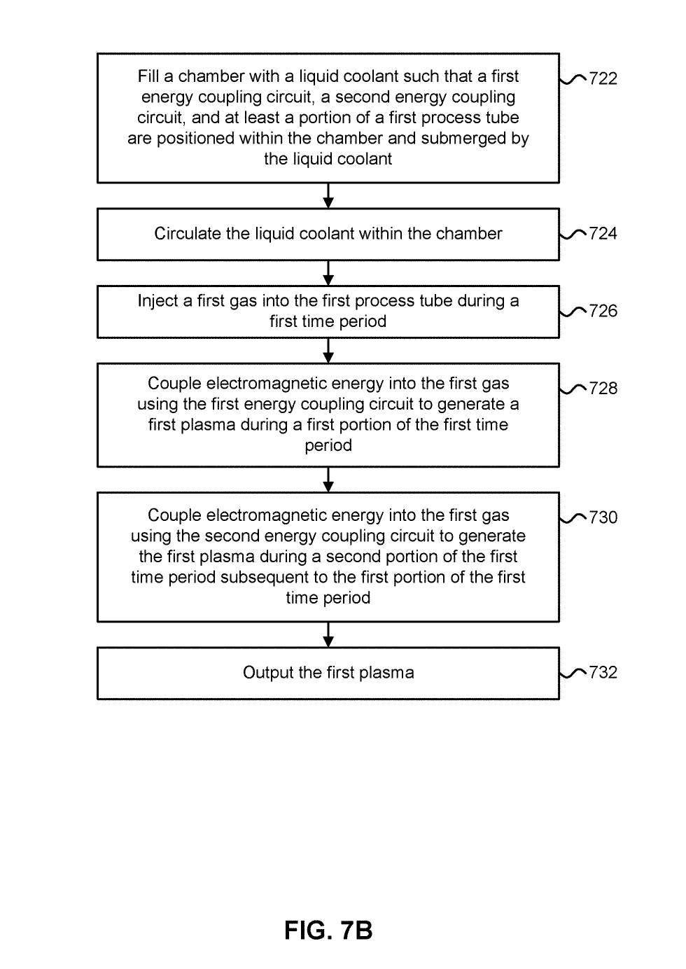

FIG. 7A is a flowchart describing one embodiment of a process for generating a plasma using an external plasma system. In one embodiment, the process of FIG. 7A may be performed by an external plasma system, such as the external plasma systems depicted in FIGS. 6A-6B and 6E.

In step 702, a chamber is filled with a liquid coolant such that a first energy coupling circuit, a second energy coupling circuit, and at least a portion of a first process tube are positioned within the chamber and submerged by the liquid coolant. In step 704, the liquid coolant is circulated within the chamber. The liquid coolant may be circulated within the chamber such that forced convection occurs to remove heat from the first process tube during operation of the external plasma system. In step 706, a first gas is injected or inserted into the first process tube. The first gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}). In step 708, electromagnetic energy is coupled (e.g., inductively coupled or capacitively coupled) into the first gas using the first energy coupling circuit while coupling electromagnetic energy into the first gas using the second energy coupling circuit. In step 710, a first plasma is outputted from the first process tube while coupling electromagnetic energy into the first gas using the first energy coupling circuit and coupling electromagnetic energy into the first gas using the second energy coupling circuit. In one example, the first plasma may be outputted and used for semiconductor processing applications, such as a deposition step or process chamber cleaning.

FIG. 7B is a flowchart describing one embodiment of a process for generating a plasma using an external plasma system. In one embodiment, the process of FIG. 7B may be performed by an external plasma system, such as the external plasma systems depicted in FIGS. 6A-6B and 6E.

In step 722, a chamber is filled with a liquid coolant such that a first energy coupling circuit, a second energy coupling circuit, and at least a portion of a first process tube are positioned within the chamber and submerged by the liquid coolant. In step 724, the liquid coolant is circulated within the chamber. The liquid coolant may be circulated within the chamber such that forced convection occurs to remove heat from the first process tube during operation of the external plasma system. In step 726, a first gas is injected or inserted into the first process tube during a first time period. The first gas may comprise a gas such as hydrogen, helium, nitrogen, oxygen, clean dry air (CDA), neon, argon, krypton, xenon, NF3, or methane (CH4) and other gaseous hydrocarbon derivatives (CₓH_{y}). In step 728, electromagnetic energy is coupled (e.g., inductively coupled or capacitively coupled) into the first gas using the first energy coupling circuit to generate a first plasma during a first portion of the first time period. In step 730, electromagnetic energy is coupled (e.g., inductively coupled or capacitively coupled) into the first gas using the second energy coupling circuit to generate the first plasma during a second portion of the first time period subsequent to the first portion of the first time period. In some cases, the first time period may correspond with igniting the first plasma while the second time period may correspond with maintaining the first plasma after the first plasma has been ignited. In step 732, the first plasma is outputted from the first process tube or from the external plasma system. In one example, the first plasma may be outputted and used for semiconductor processing applications, such as a deposition step or process chamber cleaning.

In some embodiments, an external plasma system, such as the external plasma systems depicted in FIGS. 1, 4A-4B, 4D, 6A-6B, and 6E may generate a plasma for plasma processes. The plasma processes may be used for PVD, CVD, or PE CVD depositions resulting in a wide variety of films such as conductive metals, graphenes and dielectric materials like metal oxides, oxy-nitrides and nitrides SiO2, SixOyNz, AlxOy, TixOy, C6n, or polymer films. The plasma system may be used to etch or remove metals, metal-oxides, oxides, nitrides, polymers and other such films or materials.

One embodiment of the disclosed technology includes inserting a first gas into a first process tube, inserting a second gas into a second process tube, generating a first plasma within the first process tube by coupling electromagnetic energy into the first gas using a first energy coupling device that is submerged by a liquid coolant, and generating a second plasma within the second process tube by coupling electromagnetic energy into the second gas using a second energy coupling device that is submerged by the liquid coolant. In some cases, the first energy coupling device may include a C-shaped magnetic core and the first process tube may be positioned within an opening of the C-shaped magnetic core between the ends of the C-shaped magnetic core.

One embodiment of the disclosed technology includes submerging a first energy coupling circuit, a second energy coupling circuit, and a first process tube in a liquid coolant. The method further comprises inserting a first gas into the first process tube and coupling electromagnetic energy into the first gas using the first energy coupling circuit and the second energy coupling circuit such that a first plasma is generated within the first process tube while the first energy coupling circuit, the second energy coupling circuit, and at least a portion of the first process tube are submerged by the liquid coolant. In some cases, the first energy coupling circuit may comprise a C-shaped magnetic core and the first process tube may be positioned within an opening of the C-shaped magnetic core between the ends of the C-shaped magnetic core.

In some embodiments, the first energy coupling circuit may couple electromagnetic energy into the first gas during a first period of time and the second energy coupling circuit may couple electromagnetic energy into the first gas during a second period of time subsequent to the first period of time (e.g., only the first energy coupling circuit may couple electromagnetic energy into the first gas during the first period of time). In other embodiments, the first energy coupling circuit may couple electromagnetic energy into the first gas during a first period of time and the second energy coupling circuit may couple electromagnetic energy into the first gas during the first period of time. In some cases, the first energy coupling circuit may comprise an inductive circuit configured to inductively couple electromagnetic energy into the first gas and the second energy coupling circuit may comprise a capacitive circuit configured to capacitively couple electromagnetic energy into the first gas.

One embodiment of the disclosed technology includes a plasma system comprising a chamber containing a liquid coolant, a first process tube, and a magnetic core positioned within the chamber. The magnetic core configured to cause a plasma to be generated within the first process tube while the magnetic core and at least a portion of the first process tube are submersed within the liquid coolant. The magnetic core configured to inductively couple electromagnetic energy into a first gas contained within the first process tube while the magnetic core and the portion of the first process tube are submersed within the liquid coolant. In some cases, the magnetic core may comprise a C-shaped magnetic core and the first process tube may be positioned within an opening of the C-shaped magnetic core between the ends of the C-shaped magnetic core. The plasma system may also include a second process tube and the magnetic core may be configured to cause a second plasma different from the plasma to be generated within the second process tube while the magnetic core and at least a portion of the second process tube are submersed within the liquid coolant. The magnetic core may be configured to inductively couple electromagnetic energy into a second gas contained within the second process tube while the magnetic core and the portion of the second process tube are submersed within the liquid coolant.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments and do not necessarily refer to the same embodiment.

For purposes of this document, a connection may be a direct connection or an indirect connection (e.g., via another part). In some cases, when an element is referred to as being connected or coupled to another element, the element may be directly connected to the other element or indirectly connected to the other element via intervening elements. When an element is referred to as being directly connected to another element, then there are no intervening elements between the element and the other element.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A plasma system, comprising:
a chamber containing a liquid coolant;
a first process tube; and
a magnetic core positioned within the chamber, the magnetic core configured to cause a plasma to be generated within the first process tube while the magnetic core and at least a portion of the first process tube are submersed within the liquid coolant, the magnetic core configured to inductively couple electromagnetic energy into a first gas contained within the first process tube while the magnetic core and the portion of the first process tube are submersed within the liquid coolant.

2. The plasma system of claim 1, wherein:
the magnetic core comprises a C-shaped magnetic core; and
the first process tube is positioned within an opening of the C-shaped magnetic core between the ends of the C-shaped magnetic core.

3. The plasma system of claim 2, wherein:
the C-shaped magnetic core includes a pair of pointed ends; and
the magnetic core configured to inductively couple electromagnetic energy into the first gas contained within the first process tube while the first process tube is positioned between the pair of pointed ends.

4. The plasma system of claim 1, further comprising:
a second process tube, the magnetic core configured to cause a second plasma different from the plasma to be generated within the second process tube while the magnetic core and at least a portion of the second process tube are submersed within the liquid coolant, the magnetic core configured to inductively couple electromagnetic energy into a second gas contained within the second process tube while the magnetic core and the portion of the second process tube are submersed within the liquid coolant.

5. The plasma system of claim 1, further comprising:
a capacitor, the capacitor configured to capacitively couple electromagnetic energy into the first gas contained within the first process tube while the magnetic core inductively couples electromagnetic energy into the first gas contained within the first process tube.

6. The plasma system of claim 1, wherein:
the liquid coolant comprises a dielectric liquid; and
the magnetic core comprises a doughnut-shaped magnetic core.

7. A method for operating a plasma system, comprising:
submerging a first energy coupling circuit, a second energy coupling circuit, and a first process tube in a liquid coolant;
inserting a first gas into the first process tube; and
coupling electromagnetic energy into the first gas using the first energy coupling circuit and the second energy coupling circuit such that a first plasma is generated within the first process tube while the first energy coupling circuit, the second energy coupling circuit, and at least a portion of the first process tube are submerged by the liquid coolant.

8. The method of claim 7, wherein:
the first energy coupling circuit comprises a C-shaped magnetic core; and
the first process tube is positioned within an opening of the C-shaped magnetic core between the ends of the C-shaped magnetic core.

9. The method of claim 8, wherein:
the C-shaped magnetic core includes a pair of pointed ends; and
the coupling electromagnetic energy into the first gas includes coupling the electromagnetic energy into the first gas while the first process tube is positioned between the pair of pointed ends.

10. The method of claim 7, wherein:
the first energy coupling circuit couples electromagnetic energy into the first gas during a first period of time and the second energy coupling circuit couples electromagnetic energy into the first gas during a second period of time subsequent to the first period of time.

11. The method of claim 7, wherein:
the first energy coupling circuit couples electromagnetic energy into the first gas during a first period of time and the second energy coupling circuit couples electromagnetic energy into the first gas during the first period of time.

12. The method of claim 7, wherein:
the liquid coolant comprises a dielectric liquid;
the first energy coupling circuit comprises an inductive circuit configured to inductively couple electromagnetic energy into the first gas; and
the second energy coupling circuit comprises a capacitive circuit configured to capacitively couple electromagnetic energy into the first gas.

13. A method for operating a plasma system, comprising:
inserting a first gas into a first process tube;
inserting a second gas into a second process tube;
generating a first plasma within the first process tube by coupling electromagnetic energy into the first gas using a first energy coupling device that is submerged by a liquid coolant; and
generating a second plasma within the second process tube by coupling electromagnetic energy into the second gas using a second energy coupling device that is submerged by the liquid coolant.

14. The method of claim 13, wherein:
the first energy coupling device includes a C-shaped magnetic core; and
the first process tube is positioned within an opening of the C-shaped magnetic core between the ends of the C-shaped magnetic core.

15. The method of claim 14, wherein:
the C-shaped magnetic core includes a pair of pointed ends; and
the coupling electromagnetic energy into the first gas using the first energy coupling device includes coupling the electromagnetic energy into the first gas while the first process tube is positioned between the pair of pointed ends.

16. The method of claim 13, wherein:
the generating the first plasma within the first process tube includes coupling electromagnetic energy into the first gas using the first energy coupling device and a third energy coupling device that is submerged by the liquid coolant.

17. The method of claim 16, wherein:
the first energy coupling device comprises an inductive circuit configured to inductively couple electromagnetic energy into the first gas; and
the third energy coupling device comprises a capacitive circuit configured to capacitively couple electromagnetic energy into the first gas.

18. The method of claim 16, wherein:
the first energy coupling device couples electromagnetic energy into the first gas during a first period of time and the third energy coupling device couples electromagnetic energy into the first gas during a second period of time subsequent to the first period of time.

19. The method of claim 16, wherein:
the first energy coupling device couples electromagnetic energy into the first gas during a first period of time and the third energy coupling device couples electromagnetic energy into the first gas during the first period of time.

20. The method of claim 16, wherein:
the liquid coolant comprises a dielectric liquid;
the first gas is one of hydrogen, helium, nitrogen, oxygen, neon, argon, fluorine, krypton, xenon, nitrogen trifluoride, or methane;
the first process tube comprises a ceramic tube; and
the third energy coupling device comprises a capacitor with electrodes that are arranged on a surface of the first process tube.
